(19) United States
(12) Patent Application Publication
(10) Pub. No.: US 2020/0263056 A1
(43) Pub. Date: Aug. 20, 2020

(54) POLISHING COMPOSITION AND POLISHING METHOD

(71) Applicant: AGC INC., Chiyoda-ku (JP)

(72) Inventors: Masatoshi AKAJI, Tokyo (JP); Nobuyuki TAKAGI, Tokyo (JP); Tomoo KATO, Tokyo (JP)

(73) Assignee: AGC INC., Chiyoda-ku (JP)

(21) Appl. No.: 16/790,812

(22) Filed: Feb. 14, 2020

(30) Foreign Application Priority Data
Feb. 19, 2019 (JP) 2019-027371
Jan. 16, 2020 (JP) 2020-005516

(51) Int. Cl. C09G 1/02; H01L 21/321; H01L 21/768

(52) U.S. Cl. CPC C09G 1/02; H01L 21/7684; H01L 21/3212

(57) ABSTRACT

A polishing composition include a compound represented by the following formula (1), a cerium oxide particle, and water. R¹ is S⁻, SR¹¹ where R¹¹ is a hydrogen atom or a hydrocarbon group optionally containing a hetero atom, N⁻R¹² where R¹² is a hydrogen atom or a hydrocarbon group optionally containing a hetero atom, NR¹³R¹⁴ where R¹³ and R¹⁴ are each independently a hydrogen atom or a hydrocarbon group optionally containing a hetero atom, or R¹³ and R¹⁴ are combined with each other to form a heterocycle, or N=NR¹⁵ where R¹⁵ is a hydrocarbon group; R² is a hydrocarbon group optionally containing a hetero atom; X⁺ is a monovalent cation; n is 1 in the case where R¹ is S⁻ or N⁻R¹² and is 0 in the case where R¹ is other than S⁻ and N⁻R¹².

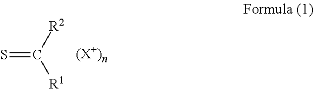

### CROSS-REFERENCE TO RELATED APPLICATIONS

This application claims priority from Japanese Patent Application No. 2019-027371 filed on Feb. 19, 2019 and Japanese Patent Application No. 2020-005516 filed on Jan. 16, 2020, the entire subject matters of which are incorporated herein by reference.

### BACKGROUND OF INVENTION

### Technical Field

The present invention relates to a polishing composition and a polishing method. Particularly, it relates to a polishing composition for chemical mechanical polishing in the production of semiconductor integrated circuits and a polishing method using the polishing composition.

### Background Art

In recent years, with the achievement of high integration and high functionalization of semiconductor integrated circuits, a micro-fabrication technique for miniaturization and densification of semiconductor elements has been developed. Hitherto, in the production of a semiconductor integrated circuit device (hereinafter referred to as semiconductor device), in order to avoid a problem that unevenness (step) of layer surface exceeds the depth of focus of lithography and thus sufficient resolution cannot be obtained, an interlayer insulating film, embedded wiring, and the like have been planarized using chemical mechanical polishing (hereinafter referred to CMP).

Heretofore, copper or tungsten has been used in the embedded wiring but, since a crystal grain boundary is present in copper, resistance increases, so that there is a limitation for thinning. Moreover, also as for tungsten, there is a limitation for thinning. Therefore, the use of a metal having low resistance and capable of being thinned, such as cobalt, ruthenium, or molybdenum, in the embedded wiring, has been performed or investigated.

In CMP relating to wiring formation, there is a high need for the development of a novel polishing composition depending on such a change in the metal material for the embedded wiring. Since polishing with extremely high accuracy is required for the polishing composition for CMP as compared with polishing compositions for simple mechanical polishing, extremely precise adjustment is necessary.

Of the above metals capable of being thinned, polishing compositions for CMP for cobalt are common. For example, Patent Document 1 describes a pH-adjusted slurry for CMP for cobalt, which contains an inhibitor, an oxidizing agent, a polishing agent and a chelating agent, each of which is composed of a specific compound, and water in predetermined ratios.

The oxidizing agent in the slurry for CMP in Patent Document 1 is a common component that is introduced for enhancing a processing speed in CMP of a metal wiring that constitutes a semiconductor device. However, the oxidizing agent causes corrosion of metal wiring and corrosion of a polishing apparatus. Furthermore, since the oxidizing agent is prone to decompose through a disproportionation reaction and it is difficult to control the concentration of the oxidizing agent in the polishing composition to a constant level, variation in the processing speed is caused and reproducibility of polishing processing is decreased. Moreover, there is a problem that the oxidizing agent degenerates the polishing stopping layer (SiN etc.) through oxidation to weaken the function as the polishing stopping layer and thus the control of polishing is made difficult.

Further, as a polishing composition for CMP for the formation of metal wiring to be used in the semiconductor device where ruthenium or molybdenum is used in the embedded wiring, Non-Patent Document 1 discloses the use of sodium percarbonate as an oxidizing agent but there is a problem that the removal rate is low, for example.
Patent Document 1: JP 2014-509064 A
Non-Patent Document 1: M. C. Turk et al. Investigation of Percarbonate Based Slurry Chemistry for Controlling Galvanic Corrosion during CMP of Ruthenium, ECS J. Solid State Sci. Technol. 2013 volume 2, issue 5, P205-P213

### SUMMARY OF INVENTION

An object of the present invention is to provide a polishing composition capable of polishing a metal layer at a high removal rate without using an oxidizing agent in a composition to be used for CMP for the formation of wiring in a semiconductor integrated circuit device using a metal having low resistance and capable of being thinned, such as cobalt, ruthenium, or molybdenum, especially using the metal as embedded wiring, and a polishing method using the polishing composition, and furthermore, is also to provide a polishing composition capable of adjusting removal rates of a metal layer and an insulating layer, and a polishing method.

A polishing composition in the present invention includes a compound represented by the following formula (1), a cerium oxide particle, and water.

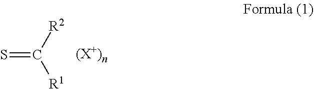

In the formula (1), R¹ is S⁻, SR¹¹ where R¹¹ is a hydrogen atom or a hydrocarbon group optionally containing a hetero atom, N⁻R¹² where R¹² is a hydrogen atom or a hydrocarbon group optionally containing a hetero atom, NR¹³R¹⁴ where R¹³ and R¹⁴ are each independently a hydrogen atom or a hydrocarbon group optionally containing a hetero atom, or R¹³ and R¹⁴ are combined with each other to form a heterocycle, or N=NR¹⁵ where R¹⁵ is a hydrocarbon group; R² is a hydrocarbon group optionally containing a hetero atom; X⁺ is a monovalent cation; n is 1 in the case where R¹ is S⁻ or N⁻R¹² and is 0 in the case where R¹ is other than S⁻ and N⁻R¹².

In the polishing composition in the present invention, it is preferred that R¹ is S⁻ or SR¹¹, and R² is NR²³R²⁴ where R²³ and R²⁴ are each independently a hydrogen atom or a hydrocarbon group optionally containing a hetero atom, or R²³ and R²⁴ are combined with each other to form a heterocycle, provided that the case where R²³ and R²⁴ are a hydrogen atom is excluded, N=NR²⁵ where R²⁵ is a hydrocarbon group, or OR²⁶ where R²⁶ is a hydrocarbon group optionally containing a hetero atom.

In the polishing composition in the present invention, it is preferred that R¹ is N⁻R¹², NR¹³R¹⁴, or N=NR¹⁵, and R² is NR⁴³R⁴⁴ where R⁴³ and R⁴⁴ are each independently a hydrogen atom or a hydrocarbon group optionally containing a hetero atom, or R⁴³ and R⁴⁴ are combined with each other to form a heterocycle, provided that the case where R⁴³ and R⁴⁴ are a hydrogen atom is excluded, or N=NR⁴⁵ where R⁴⁵ is a hydrocarbon group.

The polishing composition in the present invention preferably has a pH of 2.0 or more and 11.0 or less.

In the polishing composition in the present invention, it is preferred that a content ratio of the compound is 0.0001 mass % or more and 10 mass % or less relative to a total mass of the polishing composition.

The polishing composition in the present invention preferably includes an abrasive grain.

A polishing method in the present invention includes feeding the polishing composition according to claim 1 to a polishing pad; and bringing a target surface of a semiconductor integrated circuit device into contact with the polishing pad, and polishing the target surface through relative motion between the target surface and the polishing pad, and the target surface includes a metal containing at least one selected from the group consisting of cobalt, ruthenium, and molybdenum.

The polishing method in the present invention is for manufacturing a semiconductor integrated circuit device having a pattern where an embedded wiring of a metal containing at least one selected from the group consisting of cobalt, ruthenium, and molybdenum and an insulating layer are alternately arranged, and the insulating layer has a trench, and a metal layer composed of the metal, which is provided on the insulating layer so as to fill the trench, is polished using the polishing composition.

By the polishing composition and the polishing method of the present invention, it is possible to polish a metal layer at a high removal rate without using an oxidizing agent in a composition to be used for CMP for the formation of wiring in a semiconductor integrated circuit device using a metal having low resistance and capable of being thinned, such as cobalt, ruthenium, or molybdenum, especially using the metal as embedded wiring. The polishing composition can polish a metal layer at a high removal rate, when the composition does not contain an oxidizing agent, without causing corrosion of metal wiring and corrosion of a polishing apparatus which are caused by such an oxidizing agent. Furthermore, in CMP for the formation of wiring in the semiconductor integrated circuit device, in the case of using a polishing stopping layer, sufficiently controlled polishing is possible without weakening the function of the polishing stopping layer. Moreover, it is also possible to adjust the removal rates of the metal layer and the insulating layer.

### BRIEF DESCRIPTION OF DRAWINGS

FIG. 1 is a cross-sectional view of a semiconductor integrated circuit device schematically illustrating a polishing step (before polishing) during the formation of embedded wiring by CMP.

FIG. 2 is a cross-sectional view of a semiconductor integrated circuit device schematically illustrating a polishing step (after polishing) during the formation of embedded wiring by CMP.

FIG. 3 is a view of a polishing apparatus, as an example, which can be used for the polishing method of the present invention.

### DETAILED DESCRIPTION OF THE INVENTION

Embodiments of the present invention are described as follows with reference to drawings. The present invention should not be construed as being limited to the following embodiments and the other embodiments may be encompassed within the scope of the present invention as long as they conform to the gist of the present invention.

In the present description, the compound represented by the formula (1) is referred to as compound (1). Also, in a compound or group represented by the other formula, formula number is used as abbreviation of the compound or group, instead of compound name or group name.

The term “ . . . to . . . ” that shows a numerical range includes the numerals after and before the “to” as the upper limit and lower limit, respectively.

The polishing composition of the present invention (hereinafter also referred to as “present polishing composition”) includes the compound (1) represented by the above formula (1) and water.

The present polishing composition is suitably used in the use applications where a metal layer to be used for the formation of embedded wiring in a semiconductor integrated circuit. The metal layer may be a metal layer to be embedded wiring or a metal layer other than embedded wiring, like a barrier layer to be used for the formation of copper wiring. The present polishing composition is particularly suitably used for polishing a metal layer to be embedded wiring.

The metal constituting the metal layer is preferably a metal (hereinafter also referred to as “metal M”) containing at least one selected from the group consisting of cobalt (Co), ruthenium (Ru), and molybdenum (Mo). Of these, the advantages of the present invention are especially remarkably obtained in the case where the metal M contains Ru. The metal M may contain either one of Co, Ru. or Mo and may contain two or more thereof. Moreover, the metal may contain a metal other than Co, Ru, and Mo. In the case where the metal M contains a plurality of metals, it may be an alloy or a mixture thereof.

The following describes the case of application of the polishing composition to a semiconductor integrated circuit device including metal wiring composed of the metal M, but the polishing composition in the present invention may be used in other cases as long as it is used for metal wiring polishing.

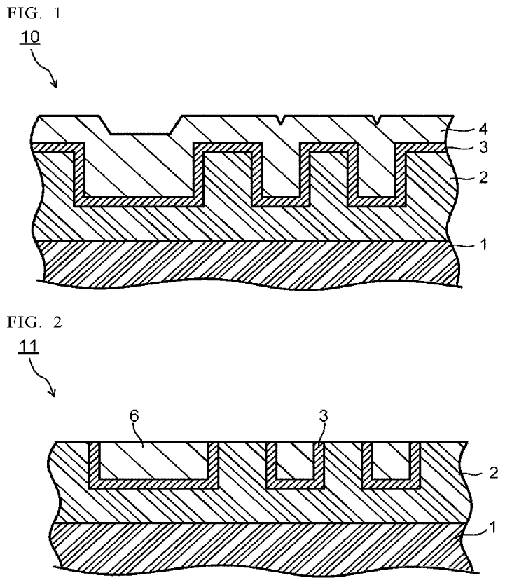

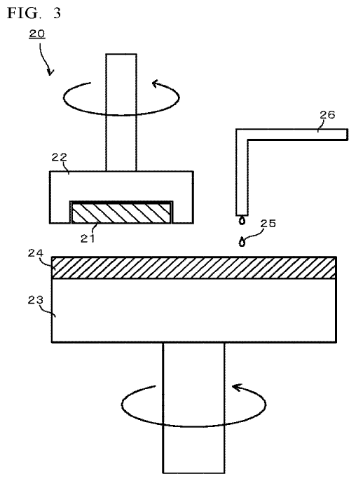

FIG. 1 and FIG. 2 are cross-sectional views of a schematically illustrated semiconductor integrated circuit device in order to describe polishing steps during the formation of embedded wiring by CMP. FIG. 1 shows the state before polishing and FIG. 2 shows the state after polishing. The configuration of each member in these figures is typical configuration and the present invention is not limited thereto.

In the semiconductor integrated circuit device 10 before polishing as shown in FIG. 1, an insulating layer 2, a polishing stopping layer 3, and a metal layer 4 composed of the metal M are formed on/above a semiconductor substrate 1 in this order. The insulating layer 2 has a trench and the polishing stopping layer 3 is formed on the insulating layer 2 so as to follow the surface shape of the insulating layer 2. The metal layer 4 is formed on the polishing stopping layer 3 so as to fill the trench.

FIG. 2 is a cross-sectional view of a semiconductor integrated circuit device 11 having a pattern where embedded wiring 6 and the insulating layer 2 are alternately arranged, after CMP is performed using the present polishing composition for the semiconductor integrated circuit device 10 before polishing shown in FIG. 1 as a polishing target, thereby polishing the metal layer 4 alone (first polishing step) and then the metal layer 4, the polishing stopping layer 3, and the insulating layer 2 are polished (second polishing step) to planarize the surface.

Since the present polishing composition contains the compound (1), for example, in CMP for the formation of wiring in the semiconductor integrated circuit device shown in FIG. 1 and FIG. 2, even when an oxidizing agent is not used, the metal layer, especially the metal layer composed of a metal containing at least one selected from the group consisting of cobalt, ruthenium, and molybdenum can be polished at a high removal rate.

By the present polishing composition, in the first polishing step where the metal layer 4 alone is polished, a high removal rate can be achieved and the composition can contribute to an improvement in production efficiency. Further, in the second polishing step where the metal layer 4, the polishing stopping layer 3, and the insulating layer 2 are polished, the metal layer 4, the polishing stopping layer 3, and the insulating layer 2 can be evenly polished and it is possible to perform polishing that ensures the planarity of the target surface. By the present polishing composition, in the case of using no oxidizing agent, the metal M constituting the embedded wiring 6 to be obtained is hardly corroded and a highly reliable semiconductor integrated circuit device 11 can be obtained. Moreover, there does not arise any problem such as corrosion of the polishing apparatus. Details of the polishing method are described below.

The following describes individual components contained in the polishing composition of the present invention and pH. The present polishing composition contains the compound (1), a cerium oxide particle, and water as essential components. The present polishing composition may contain a pH adjusting agent, abrasive grains, a corrosion inhibitor, a dispersing agent and the like, as optional components.

### <Compound (1)>

The compound (1) is represented by the following formula (1).

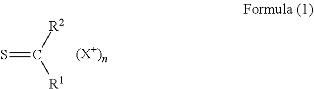

In the formula (1), R¹ is S⁻, SR¹¹ where R¹¹ is a hydrogen atom or a hydrocarbon group optionally containing a hetero atom, N⁻R¹² where R¹² is a hydrogen atom or a hydrocarbon group optionally containing a hetero atom, NR¹³R¹⁴ where R¹³ and R¹⁴ are each independently a hydrogen atom or a hydrocarbon group optionally containing a hetero atom, or R¹³ and R¹⁴ are combined with each other to form a heterocycle, or N=NR¹⁵ where R¹⁵ is a hydrocarbon group; R² is a hydrocarbon group optionally containing a hetero atom; X⁺ i s a monovalent cation; n is 1 in the case where R¹ is S⁻ or N⁻R¹² and is 0 in the case where R¹ is other than S⁻ and N⁻R¹².

In the description of the formula (1), the hydrocarbon group may be saturated or unsaturated and may be linear, branched, cyclic, or a structure resulting from the combination thereof. The number of carbon atoms is preferably 1 to 11 and more preferably 1 to 8. As the hetero atom, S, N, O, and the like may be mentioned. The hetero atom may be present between carbon-carbon atoms or may be present at the end on the side where the hydrocarbon group is bonded. Moreover, the hetero atom may be present in such a form that a hydrogen atom bonding to a carbon atom is replaced therewith or may be contained in a group with which a hydrogen atom bonding to a carbon atom is replaced. As the group which contains the hetero atom and with which the hydrogen atom is replaced, specific examples thereof include a hydroxyl group, a mercapto group, and an amino group.

In the compound (1), R¹ is S⁻, SR¹¹, N⁻R¹², NR¹³R¹⁴, or N=NR¹⁵, provided that R¹¹ to R¹⁵ are as described above. In R¹, the atom bonded to the carbon atom of S=C is two kinds, i.e., S or N. Namely, the compound (1) can be roughly classified into two kinds depending on the kind of R¹. The compound (1) in the case where the atom bonded to the carbon atom of S=C in R¹ is S is hereinafter referred to as compound (1S). The compound (1) in the case where the atom bonded to the carbon atom of S=C in R¹ is N is hereinafter referred to as compound (1N).

In the case where R¹ is S⁻ or NR⁻R¹², the compound (1) is a monovalent anion and has X⁺ that is a monovalent cation, as a counter cation. The kind of X⁺ is not particularly limited and is appropriately selected depending on the kind of R¹ or R².

In the compound (1), R² is a hydrocarbon group optionally containing a hetero atom. The kinds of the hydrocarbon group and the hetero atom are as described above. The kind of R² may be appropriately selected depending on the kind of R¹. Even when R¹ is any one of them, the atom bonded to the carbon atom of S=C in R² is preferably a hetero atom. The following describes preferable embodiments in the compound (1S) and the compound (1N).

In the compound (1S), the case where R¹ is S⁻ is referred to as compound (1Si) and the case where R¹ is SR¹¹ is referred to as compound (1Sii)

In the case of the compound (1Si), R₂ may be an alkyl group having 1 to 7 carbon atoms, an aryl group having 6 to 10 carbon atoms, or an aralkyl group having 7 to 11 carbon atoms. The alkyl groups of these hydrocarbon groups may be linear, branched, cyclic, or a structure resulting from the combination thereof. Moreover, these hydrocarbon groups may have a hetero atom as an atom present between carbon-carbon atoms and/or an atom bonded to the carbon atom of S=C. Further, they may have a hetero atom in the atom or substituent with which the hydrogen atom bonded to a carbon atom is substituted.

In the compound (1Si), in R², the atom bonded to the carbon atom of S=C is preferably a hetero atom and the hetero atom is preferably N or O. Specific examples of R² include NR²³R²⁴ where R²³ and R²⁴ are each independently a hydrogen atom or a hydrocarbon group optionally containing a hetero atom, or R²³ and R²⁴ are combined with each other to form a heterocycle, provided that the case where R²³ and R²⁴ are a hydrogen atom is excluded, N=NR²⁵ where R²⁵ is a hydrocarbon group, and OR²⁶ where R²⁶ is a hydrocarbon group optionally containing a hetero atom.

As for each of R²³, R²⁴, R²⁵, and R²⁶, examples thereof include an alkyl group having 1 to 7 carbon atoms, an aryl group having 6 to 10 carbon atoms, and an aralkyl group having 7 to 11 carbon atoms. In the case of the alkyl group, the number of carbon atoms is more preferably 1 to 3. In the case of the aryl group, the number of carbon atoms is more preferably 6 to 7. In the case of the aralkyl group, the number of carbon atoms is more preferably 7 to 8. The alkyl group, or the alkylene group or alkyl group included in the aryl group or aralkyl group may be linear, branched, cyclic, or a structure resulting from the combination thereof.

Moreover, the hydrocarbon groups in R²³, R²⁴, and R²⁶ may have a hetero atom as an atom present between carbon-carbon atoms and/or an atom bonded to the carbon atom of S=C. Further, they may have a hetero atom in the atom or substituent with which the hydrogen atom bonded to a carbon atom is substituted. In the case where R²³ and R²⁴ are combined with each other to form a ring, the number of the member of the heterocycle containing N may be 3 to 7 and is preferably 5 to 6. Furthermore, the hydrogen atom bonded to the atom constituting the ring of the heterocycle containing N may be replaced with an alkyl group having 1 to 3 carbon atoms, an aryl group having 6 to 10 carbon atoms, an aralkyl group having 7 to 11 carbon atoms, or an OH group.

Specifically, R² in the compound (1Si) is preferably NR²³R²⁴ or OR²⁶. Specific examples of the compound (1Si) are shown in Table 1. In Table 1, “Ph” indicates a phenyl group. Specific examples of X⁺ are described below. Moreover, of the compounds (1Si) shown in Table 1, chemical formulae are shown for preferable compounds. In Table 1, chemical formula numbers are also shown.

TABLE 1

| Compound | | | | | | | Chemical formula |
|---|---|---|---|---|---|---|---|
| abbreviation | R¹ | R² | R²³ | R²⁴ | R²⁶ | n | Number |
| (1Si-1) | S⁻ | NR²³R²⁴ | CH₃ | CH₃ | — | 1 | (1Si-1) |
| (1Si-2) | | | C₂H₅ | C₂H₅ | — | | (1Si-2) |
| (1Si-3) | | | CH₂—Ph | CH₂—Ph | — | | (1Si-3) |
| (1Si-4) | | | —(CH₂)₄— | | — | | (1Si-4) |
| (1Si-5) | | | —(CH₂)₅— | | — | | (1Si-5) |
| (1Si-6) | | | —(CH₂)₄—CH(CH₃)— | | — | | (1Si-6) |
| (1Si-7) | | | —(CH₂)₆— | | — | | (1Si-7) |
| (1Si-8) | | | (CH₂)₂CH₃ | (CH₂)₂CH₃ | — | | — |
| (1Si-9) | | | (CH₂)₃CH₃ | (CH₂)₃CH₃ | — | | — |
| (1Si-10) | | | (CH₂)₂—OH | (CH₂)₂—OH | — | | — |
| (1Si-21) | | OR²⁶ | — | — | CH₂CH₃ | | (1Si-21) |
| (1Si-22) | | | — | — | (CH₂)₂CH₃ | | (1Si-22) |
| (1Si-23) | | | — | — | CH(CH₃)₂ | | (1Si-23) |
| (1Si-24) | | | — | — | (CH₂)₃CH₃ | | (1Si-24) |
| (1Si-25) | | | — | — | (CH₂)₄CH₃ | | (1Si-25) |

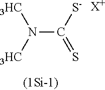

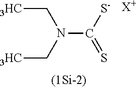

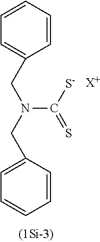

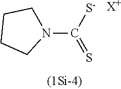

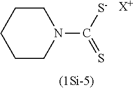

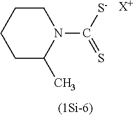

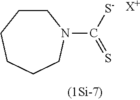

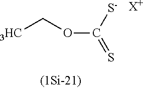

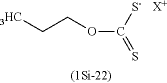

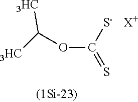

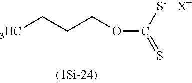

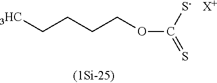

In the above individual formulae, X⁺ represents a monovalent cation.

As X⁺ in the compound (1Si), specific examples thereof include alkali metal ions such as Na⁺ and K⁺, NH₄⁺, NH₃⁺R⁵¹, NH₂⁺R⁵²R⁵³, NH⁺R⁵⁴R⁵⁵R⁵⁶, N⁺R⁵⁷R⁵⁸R⁵⁹R⁶⁰, and the like. As for each of R⁵¹, R⁵², R⁵³, R⁵⁴, R⁵⁵, R⁵⁶, R⁵⁷, R⁵⁸, R⁵⁹, and R⁶⁰, examples thereof include an alkyl group having 1 to 18 carbon atoms, an aryl group having 6 to 12 carbon atoms, and an aralkyl group having 7 to 13 carbon atoms. In the case of the alkyl group, the number of carbon atoms is more preferably 1 to 4. In the case of the aryl group, the number of carbon atoms is more preferably 6 to 7. In the case of the aralkyl group, the number of carbon atoms is more preferably 7 to 8. The alkyl group, or the alkylene group or alkyl group included in the aryl group or aralkyl group may be linear, branched, cyclic, or a structure resulting from the combination thereof.

In NH₂⁺R⁵²R⁵³, R⁵² and R⁵³ may be combined with each other to form a ring. In NH⁺R⁵⁴R⁵⁵R⁵⁶, any two of R⁵⁴, R⁵⁵, and R⁵⁶ may be combined with each other to form a ring. In N⁺R⁵⁷R⁵⁸R⁵⁹R⁶⁰, any two of R⁵⁷, R⁵⁸, R⁵⁹, and R⁶⁰, may be combined with each other to form a ring. In the cases, the number of the members of the heterocycle containing N may be 3 to 7 and is preferably 5 to 6. Furthermore, the hydrogen atom bonded to the atom constituting the ring of the heterocycle containing N may be replaced with an alkyl group having 1 to 3 carbon atoms, an aryl group having 6 to 10 carbon atoms, or an aralkyl group having 7 to 11 carbon atoms.

As NH₂⁺R⁵²R⁵³, specific examples thereof include monovalent cations represented by the following formulae (X-1) to (X-4).

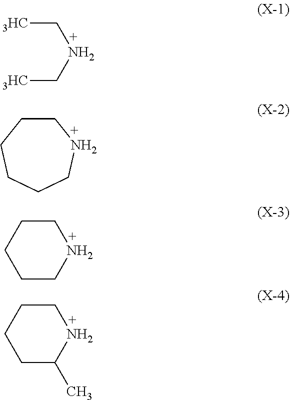

In the compound (1Si), in the case where R² is NR²³R²⁴, X⁺ is preferably Na⁺, K⁺, NH₄⁺, NH₂⁺R⁵²R⁵³, or the like. Moreover, in the case where X⁺ is NH₂⁺R⁵²R⁵³, R²³ and R²⁴ are preferably the same as R⁵² and R⁵³, respectively. For example, X⁺ in the case of the compound (1Si-2) is preferably the cation (X-1). Similarly, X⁺ in the case of the compound (1Si-5) is preferably the cation (X-3), X⁺ in the case of the compound (1Si-6) is preferably the cation (X-4), and X⁺in the case of the compound (1Si-7) is preferably the cation (X-2).

In the compound (1Si), in the case where R² is OR²⁶, X⁺ is preferably an alkali metal ion such as Na⁺ or K⁺ and more preferably K⁺. The compound (1Si) may be used as a hydrate, if necessary. For example, in the compound (1Si-1), in the case where X⁺ is Na⁺, a dihydrate of the compound is common and such a hydrate may be used in the present polishing composition. However, in that case, the content of the compound (1) to be mentioned below is shown as an amount in the state that H₂O of the hydrate is removed.

In the compound (1Sii), R¹ is SR¹¹, and R¹¹ is preferably a hydrocarbon group optionally containing a hetero atom. As R¹¹, examples thereof include S—C(═S)—R³. Here, as R³, examples thereof include the same groups as in the case of R².

R² in the compound (1Sii) is the same as R² in the case of the above compound (1Si) including the preferable embodiments. As the compound (1Sii), specific examples thereof include the following compound (1Sii-1).

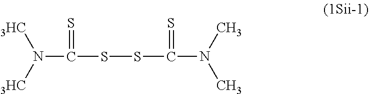

In the compound (1N), the case where R¹ is NR¹³R¹⁴ is referred to as compound (1Ni), the case where R¹ is N=NR¹⁵ is referred to as compound (1Nii), and the case where R¹ is N⁻R¹² is referred to as compound (1Niii).

R¹³ and R¹⁴ of NR¹³R¹⁴ in the compound (1Ni) are each independently a hydrogen atom or a hydrocarbon group optionally containing a hetero atom, or R¹³ and R¹⁴ are combined with each other to form a heterocycle. Both of R¹³ and R¹⁴ are preferably a hydrogen atom, and it is more preferred that one of R¹³ and R¹⁴ is a hydrogen atom and the other is a hydrocarbon group that contains a hetero atom. As the hydrocarbon group optionally containing a hetero atom, examples thereof include an alkyl group having 1 to 7 carbon atoms, an aryl group having 6 to 10 carbon atoms, and an aralkyl group having 7 to 11 carbon atoms. In the case of the alkyl group, the number of carbon atoms is more preferably 1 to 3. In the case of the aryl group, the number of carbon atoms is more preferably 6 to 7. In the case of the aralkyl group, the number of carbon atoms is more preferably 7 to 8. The alkyl group, or the alkylene group or alkyl group included in the aryl group or aralkyl group may be linear, branched, cyclic, or a structure resulting from the combination thereof.

Moreover, these hydrocarbon groups may have a hetero atom as an atom present between carbon-carbon atoms and/or an atom bonded to the nitrogen atom. As the hetero atom bonded to the nitrogen atom, a nitrogen atom is preferred. In the case where any one of R¹³ and R¹⁴ is a hydrocarbon group that contains a hetero atom, as the group, NR³³R³⁴ is preferred. R³³ and R³⁴ are each independently a hydrogen atom or a hydrocarbon group optionally containing a hetero atom, or R³³ and R³⁴ are combined with each other to form a heterocycle.

In the compound (1Ni), as R², examples thereof include a carbon atom and a hydrocarbon group that contains a hetero atom. In R², the atom bonded to the carbon atom of S═C is preferably a carbon atom. As R², specific examples thereof include CH₃, CH₂CH₃, C(═S)NH₂, C(═O)OCH₂CH₃, Ph, CH₂Ph, PhCl (ortho-, meta-, or para-isomer), PhCF₃ (ortho-, meta-, or para-isomer), PhOH (ortho-, meta-, or para-isomer), 2-Py, 3-Py, and 4-Py. The above “Py” indicates pyridyl group. Moreover, as R², specific examples thereof include the same groups as R² in the case of the compound (1Si). In the compound (1Ni), in R², the atom bonded to the carbon atom of S═C is preferably a hetero atom and the hetero atom is preferably a nitrogen. As R², specific examples thereof include NR⁴³R⁴⁴ where R⁴³ and R⁴⁴ are each independently a hydrogen atom or a hydrocarbon group optionally containing a hetero atom, or R⁴³ and R⁴⁴ are combined with each other to form a heterocycle, provided that the case where R⁴³ and R⁴⁴ are a hydrogen atom is excluded, and N=NR⁴⁵ where R⁴⁵ is a hydrocarbon group.

As for each of R⁴³, R⁴⁴, and R⁴⁵, examples thereof include an alkyl group having 1 to 7 carbon atoms, an aryl group having 6 to 10 carbon atoms, and an aralkyl group having 7 to 11 carbon atoms. In the case of the alkyl group, the number of carbon atoms is more preferably 1 to 3. In the case of the aryl group, the number of carbon atoms is more preferably 6 to 7. In the case of the aralkyl group, the number of carbon atoms is more preferably 7 to 8. The alkyl group, or the alkylene group or alkyl group included in the aryl group or aralkyl group may be linear, branched, cyclic, or a structure resulting from the combination thereof.

Moreover, the hydrocarbon groups in R⁴³ and R⁴⁴ may contain a hetero atom as an atom present between carbon-carbon atoms and/or an atom bonded to the carbon atom of S═C. In the case where R⁴³ and R⁴⁴ are combined with each other to form a ring, the number of the members of the heterocycle containing N may be 3 to 7 and is preferably 5 to 6. Furthermore, the hydrogen atom bonded to the atom constituting the ring of the heterocycle containing N may be replaced with an alkyl group having 1 to 3 carbon atoms, an aryl group having 6 to 10 carbon atoms, or an aralkyl group having 7 to 11 carbon atoms.

R¹⁵ of N=NR¹⁵ in the compound (1Nii) is a hydrocarbon group. As the hydrocarbon group, examples thereof include an alkyl group having 1 to 7 carbon atoms, an aryl group having 6 to 10 carbon atoms, and an aralkyl group having 7 to 11 carbon atoms. In the case of the alkyl group, the number of carbon atoms is more preferably 1 to 3. In the case of the aryl group, the number of carbon atoms is more preferably 6 to 7. In the case of the aralkyl group, the number of carbon atoms is more preferably 7 to 8. The alkyl group, or the alkylene group or alkyl group included in the aryl group or aralkyl group may be linear, branched, cyclic, or a structure resulting from the combination thereof.

As R² in the compound (1Nii), there may be mentioned groups the same as R² in the case of the compound (1Ni) and preferable embodiments may be similarly mentioned.

R¹² of N⁻R¹² in the compound (1Niii) is a hydrogen atom or a hydrocarbon group optionally containing a hetero atom. As R¹², there may be mentioned the same embodiments as in R¹³ and R¹⁴. As X⁺ in the compound (1Niii), there may be mentioned the same embodiments as X⁺ in the compound (1Si). Moreover, as R² in the compound (1Niii), there may be mentioned the same embodiments including preferable embodiments as R² in the compound (1Ni).

Specific examples of the compound (1Ni) and the compound (1Nii) are shown in Table 2. In Table 2, “Ph” indicates a phenyl group. Moreover, of the compounds (1Ni) and the compounds (1Nii) shown in Table 2, chemical formulae are shown for preferable compounds. In Table 2, chemical formula numbers are also shown.

TABLE 2

| Com- | | | | | | | | | |
|---|---|---|---|---|---|---|---|---|---|
| pound | | | | | | | | | Chemical |
| abbre- | | | | | | | | | formula |
| viation | R¹ | R¹³ | R¹⁴ | R¹⁵ | R² | R⁴³ | R⁴⁴ | R⁴⁵ | Number |
| (1Ni-1) | NR¹³R¹⁴ | H | Ph | — | NR⁴³R⁴⁴ | H | NHPh | — | (1Ni-1) |
| (1Ni-2) | | H | NHPh | — | | H | NHPh | — | (1Ni-2) |
| (1Ni-3) | | H | CH₃ | — | | H | CH₃ | — | (1Ni-3) |
| (1Ni-4) | | H | H | — | CH₃ | — | — | — | (1Ni-4) |
| (1Nii-1) | | — | — | Ph | NR⁴³R⁴⁴ | H | NHPh | — | (1Nii-1) |
| (1Nii-2) | N═NR¹⁵ | — | — | Ph | N═NR⁴⁵ | — | — | Ph | (1Nii-2) |

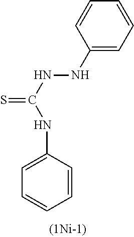 [SMILES: S=C(NNc1ccccc1)Nc1ccccc1]

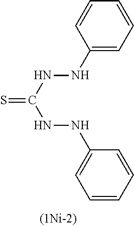 [SMILES: S=C(NNc1ccccc1)NNc1ccccc1]

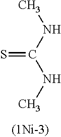

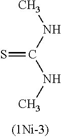

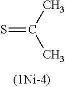

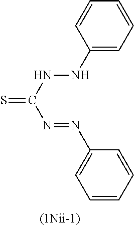 [SMILES: S=C(/N=N/c1ccccc1)NNc1ccccc1]

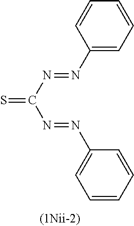 [SMILES: S=C(/N=N/c1ccccc1)/N=N/c1ccccc1]

Of these compounds (1), preferred compounds are as follows: the compounds (1Si-1) to (1Si-7), the compounds (1Sii-21) to (1Sii-25), the compounds (1Ni-1) and (1Ni-2), the compounds (1Nii-1) and (1Nii-2), and more preferred compounds are as follows: the compounds (1Si-1), (1Si-2), (1Si-4), (1Si-5), and (1Si-6). The present polishing composition may contain only one kind of the compound (1) or may contain two or more kinds thereof.

The content of the compound (1) in the present polishing composition is preferably 0.0001 mass % or more and 10 mass % or less, more preferably 0.005 mass % or more and 5 mass % or less, and further preferably 0.01 mass % or more and 1 mass % or less, relative to the total mass of the polishing composition. The content of the compound (1) in the present polishing composition is preferably 3×10⁻⁷ mol/kg or more and 7×10⁻² mol/kg or less, more preferably 2×10⁻⁵ mol/kg or more and 4×10⁻² mol/kg or less, and further preferably 4×10⁻⁵ mol/kg or more and 7×10⁻³ mol/kg or less, relative to the polishing composition.

When the content of the compound (1) is 0.0001 mass % or more, the present polishing composition can polish the metal layer, especially the metal layer composed of the metal M, at a high removal rate. When the content of the compound (1) is 10 mass % or less, the corrosion of the metal layer and the aggregation of abrasive grains can be prevented. When the content of the compound (1) is 3×10⁻⁷ mol/kg or more, the present polishing composition can polish the metal layer, especially the metal layer composed of the metal M, at a high removal rate. When the content (1) of the compound is 7×10⁻² mol/kg or less, the corrosion of the metal layer and the aggregation of abrasive grains can be prevented.

### <Abrasive Grains>

The present polishing composition contains, as an essential component, cerium oxide particles as abrasive grains. Since the present polishing composition contains cerium oxide particles, the metal layer, especially the metal layer composed of the metal M, can be polished at a high removal rate. Moreover, in the case where the mixture of the metal layer and the insulating film composed of silicon oxide or the like are present on the target surface and the mixed film is simultaneously planarized, the removal rate of the insulating film or the like can be adjusted.

The present polishing composition may contain the other common abrasive grains in addition to cerium oxide (ceria). Here, as abrasive grains that may be contained, examples thereof include fine particles composed of a metal oxide such as silicon oxide (silica), aluminum oxide (alumina), zirconium oxide (zirconia), titanium oxide (titania), chromium oxide, iron oxide, tin oxide, zinc oxide, germanium oxide, and manganese oxide, diamond, silicon carbide, boron carbide, boron nitride, and the like.

Cerium oxide particles contained in the present polishing composition are not particularly limited as long as they are particles that are used as abrasive grains. For example, cerium oxide particles produced by the method described in JP H11-12561 A or JP 2001-35818 A may be used. Namely, usable examples thereof include cerium oxide particles obtained by adding an alkali to an aqueous cerium (IV) ammonium nitrite solution to prepare a cerium hydroxide gel and filtrating, washing, and firing it, and cerium oxide particles obtained by pulverizing highly pure cerium carbonate, then firing it, and further performing pulverization and classification. Moreover, as described in JP 2010-505735 A, cerium oxide particles obtained by chemically oxidizing a cerium (III) salt in a liquid.

The particle diameter of the abrasive grains is preferably 10 nm or more and 200 nm or less in terms of average secondary particle diameter. Since the abrasive grains are present in the polishing composition in the form of aggregation particles (secondary particles) where primary particles are aggregated, preferable particle diameter of the abrasive grains is indicated as the average secondary particle diameter. When the average secondary particle diameter exceeds 200 nm, the abrasive grain diameter is too large and it becomes difficult to increase the concentration of the abrasive grains, and when the average secondary particle diameter is less than 10 nm, an improvement in the removal rate becomes difficult. The average secondary particle diameter of the abrasive grains is preferably in the range of 20 nm or more and 120 nm or less. The average secondary particle diameter is measured using a dispersion liquid in which the abrasive grains are dispersed in a dispersible medium such as pure water, and employing a particle size distribution meter of a laser diffraction/dispersion type or the like.

As the abrasive grains, cerium oxide particles may be used alone, or two or more kinds including cerium oxide particles and the other abrasive grain(s) may be used in combination. In the case where cerium oxide particles and the other abrasive grains are used in combination, cerium oxide particles are contained in an amount of preferably 0.5 mass % or more, more preferably 20 mass % or more, and particularly preferably 100 mass %, based on the abrasive grains.

In the case of using the abrasive grains, the ratio of the abrasive grains relative to the total mass of the present polishing composition is preferably 0.005 mass % or more and 10 mass % or less, more preferably 0.01 mass % or more and 5 mass % or less, further preferably 0.05 mass % or more and 2 mass % or less, still further preferably 0.05 mass % or more and 1 mass % or less, and particularly preferably 0.05 mass % or more and 0.6 mass % or less.

As the abrasive grains, an abrasive grain dispersion liquid in a state that they are dispersed in a medium beforehand may be used. As the medium, water may be preferably used.

### <Water>

The present polishing composition contains water as an essential component. The present polishing composition is typically formed by dissolving the compound (1) in a liquid medium containing water. The liquid medium in the present polishing composition is mainly composed of water and the liquid medium is preferably composed of water alone or a mixture of water and a water-soluble solvent. As water, it is preferable to use pure water which has been subjected to ion exchange to remove foreign substances. As the water-soluble solvent, examples thereof include water-soluble alcohols, water-soluble polyols, water-soluble esters, water-soluble ethers, and the like.

The liquid medium in the present polishing composition is preferably water alone or a mixed solvent of water and a water-soluble organic solvent, which contains water in an amount of 80 mass % or more, and most preferably is substantially composed of water alone. Moreover, the ratio of the liquid medium in the present polishing composition is preferably 85 mass % or more, more preferably 90 mass % or more, and particularly preferably 95 mass % or more. Substantially whole amount of the liquid medium is preferably composed of water and, in that case, the content of water in the present polishing composition is preferably 90 mass % or more and particularly preferably 95 mass % or more.

The ratio of each component of the present polishing composition means a compositional ratio during polishing. In the case where a concentrated composition for polishing is diluted before polishing and the dilute is used for polishing, the ratio of each component described above or mentioned below is a ratio in the dilute. The concentrated composition for polishing is usually diluted with a liquid medium (especially water) and therefore, in that case, the relative ratio of each component excluding the liquid medium usually does not change before and after dilution.

(pH)

The pH of the present polishing composition is preferably 2.0 or more and 11.0 or less. When the pH is in the range of 2.0 or more and 11.0 or less, the present polishing composition can polish the metal layer, especially the metal layer composed of the metal M, at a high removal rate and also is excellent in storage stability. Moreover, during transporting the polishing composition or during using the polishing composition, it can be handled more safely. The pH of the present polishing composition is more preferably 3.0 or more and 10.0 or less, particularly preferably 4.0 or more and 9.5 or less, and extremely preferably 4.5 or more and 9.5 or less.

The present polishing composition may contain various inorganic acids and organic acids or salts thereof or basic compounds as a pH adjusting agent, in order to control the pH to the specific value of 2.0 or more and 11.0 or less.

The inorganic acids or inorganic acid salts are not particularly limited and, for example, nitric acid, sulfuric acid, hydrochloric acid, phosphoric acid, and ammonium salts or potassium salts thereof may be used. The organic acids or organic acid salts are not particularly limited and, for example, carboxylic acids such as formic acid, acetic acid, oxalic acid, malic acid, and citric acid and salts thereof may be used.

The basic compound is preferably water soluble and is not particularly limited. As the basic compound, examples thereof include metal hydroxides such as lithium hydroxide, sodium hydroxide, potassium hydroxide, rubidium hydroxide, and cesium hydroxide, ammonia, quaternary ammonium hydroxides such as tetramethylammonium hydroxide (hereinafter referred to as TMAH), tetraethylammonium hydroxide, tetrapropylammonium hydroxide, and tetrabutylammonium hydroxide, organic amines such as diethylamine, trimethylamine, monoethanolamine, diethanolamine, triethanolamine, and ethylenediamine, and the like.

### <Corrosion Inhibitor>

The present polishing composition may contain a corrosion inhibitor as an optional component. As the corrosion inhibitor, a common corrosion inhibitor may be used, and examples thereof include nitrogen-containing heterocyclic compounds, nonionic surfactants, and the like.

As the nitrogen-containing heterocyclic compounds, specific examples thereof include pyrrole compounds, pyrazole compounds, imidazole compounds, triazole compounds, tetrazole compounds, pyridine compounds, pyrazine compounds, pyridazine compounds, pirindine compounds, indolizine compounds, indole compounds, isoindole compounds, indazole compounds, purine compounds, quinolizine compounds, quinoline compounds, isoquinoline compounds, naphthylidine compounds, phthalazine compounds, quinoxaline compounds, quinazoline compounds, cinnoline compounds, pteridine compounds, thiazole compounds, benzothiazole compounds, isothiazole compounds, oxazole compounds, isoxazole compounds, furazane compounds, and the like.

Of these compounds, form the viewpoint of improving planarity of surface of a polishing target, tetrazole compounds, pyrazole compounds, and triazole compounds are suitable, and triazole compounds are particularly suitable.

Of the triazole compounds, a benzotriazole group having an amino group having a group substituted with at least one hydroxyalkyl group is preferred for exhibiting the expected advantages of the present invention. Here, the number of the hydroxyalkyl groups is not particularly limited and, from the viewpoint of dispersion stability in the polishing composition, the number is preferably 1 or 2.

Moreover, the number of the carbon atoms of the alkyl group in the hydroxyalkyl group is also not particularly limited and, form the viewpoint of preventing a decrease in the removal rate of the polishing target, the number of the carbon atoms is preferably 1 to 5, more preferably 1 to 4, and further preferably 2 to 3. Further, the number of the alkyl groups in the case where the number of the hydroxyalkyl groups is two or more may be the same or different from each other and, from the viewpoint of storage stability of the compound and from the viewpoint of oxidation prevention of the compound, the number is preferably the same.

The triazole compound is preferably one having a condensed ring. For example, preferred examples thereof include one condensed with a benzene ring, a naphthalene ring, an anthracene ring and the like, from the viewpoint of stability of the compound and from the viewpoint of oxidation prevention of the polishing composition. Moreover, the triazole compound may have a substituent such as an alkyl group having 1 to 3 carbon atoms, a hydroxyl group, or a halogen atom.

Suitable examples of the triazole compound include 2,2′-∥(methyl-1H-benzotriazol-1-yl)methyl|imino|bisethanol, 1,2,3-triazole, 1,2,4-triazole, 1-methyl-1,2,4-triazole, methyl-1H-1,2,4-triazol-3-carboxylate, 1,2,4-triazol-3-carboxylic acid, methyl 1,2,4-triazol-3-carboxylate, 1H-1,2,4-triazol-3-thiol, 3,5-diamino-1H-1,2,4-triazole, 3-amino-1,2,4-triazol-5-thiol, 3-amino-1H-1,2,4-triazole, 3-amino-5-benzyl-4H-1,2,4-triazole, 3-amino-5-methyl-4H-1,2,4-triazole, 3-nitro-1,2,4-triazole, 3-bromo-5-nitro-1,2,4-triazole, 4-(1,2,4-triazol-1-yl)phenol, 4-amino-1,2,4-triazole, 4-amino-3,5-dipropyl-4H-1,2,4-triazole, 4-amino-3,5-dimethyl-4H-1,2,4-triazole, 4-amino-3,5-diheptyl-4H-1,2,4-triazole, 5-methyl-1,2,4-triazol-3,4-diamine, 1H-benzotriazole, 1-hydroxybenzotriazole, 1-aminobenzotriazole, 1-carboxybenzotriazole, 5-chloro-1H-benzotriazole, 5-nitro-1H-benzotriazole, 5-carboxy-1H-benzotriazole, 5-methyl-1H-benzotriazole, 5,6-dimethyl-1H-benzotriazole, 1-(1′,2′-dicarboxyethyl)benzotriazole, 1-[N,N-bis(hydroxyethyl)aminomethyl]benzotriazole, 1-[N,N-bis(hydroxyethyl)aminomethyl]-5-methylbenzotriazole, 1-[N,N-bis(hydroxyethyl)aminomethyl]-4-methylbenzotriazole, and the like.

Of these compounds, from the viewpoint of efficiently exhibiting the advantages of the present invention and from the viewpoint of possible realization of planarity of the target surface while obtaining a desirable removal rate, preferred examples thereof include 2,2′-[[(methyl-1H-benzotriazol-1-yl)methyl]imino]bisethanol, 1,2,3-triazole, 1H-benzotriazole, 5-methyl-1H-benzotriazole, 5,6-dimethyl-1H-benzotriazole, 1-[N,N-bis(hydroxyethyl)aminomethyl]-5-methylbenzotriazole, 1-[N,N-bis(hydroxyethyl)aminomethyl]-4-methylbenzotriazole, 1,2,3-triazole, 1,2,4-triazole, and the like.

Moreover, examples of the pyrazole compound include 1H-pyrazole, 4-nitro-3-pyrazolecarboxylic acid, 3,5-pyrazolecarboxylic acid, 3-amino-5-phenylpyrazole, 5-amino-3-phenylpyrazole, I-allyl-3,5-dimethylpyrazole, 3,4,5-tribromopyrazole, 3-aminopyrazole, 3,5-dimethylpyrazole, 3,5-di(2-pyridyl)pyrazole, 3,5-diisopropylpyrazole, 3,5-dimethyl-1-hydroxymethylpyrazole, 3,5-dimethyl-1-phenylpyrazole, 3-methylpyrazole, 1-methylpyrazole, 4-methylpyrazole, N-methylpyrazole, 3-amino-5-methylpyrazole, 3-amino-5-hydroxypyrazole, 4-amino-pyrazolo[3,4-d]pyrimidine, allopurinol, 4-chloro-1H-pyrazolo[3,4-b]pyrimidine, 3,4-dihydroxy-6-methylpyrazolo(3,4-B)-pyridine, 6-methyl-1H-pyrozolo[3,4-b]pyridine-3-amine, and the like.

Examples of the imidazole compound include imidazole, 1-methylimidazole, 2-methylimidazole, 4-methylimidazole, 1,2-dimethylimidazole, 2-ethyl-4-methylimidazole, 2-isopropylimidazole, benzimidazole, 5,6-dimethylbenzimidazole, 2-aminobenzimidazole, 2-chlorobenzimidazole, 2-methylbenzimidazole, 2-(1-hydroxyethyl)benzimidazole, 2-hydroxybenzimidazole, 2-phenylbenzimidazole, 2,5-dimethylbenzimidazole, 5-methylbenzimidazole, 5-nitrobenzimidazole, 1H-purine, 1,1′-carbonylbis-1H-imidazole, 1,1′-oxalyldiimidazole, 1,2,4,5-tetramethylimidazole, 1,2-dimethyl-5-nitroimidazole, 1-(3-aminopropyl)imidazole, 1-butylimidazole, 1-ethylimidazole, 1H-1,2,3-triazolo[4,5-b]pyridine, and the like.

Examples of the tetrazole compound include 1H-tetrazole, 5-methyltetrazole, 5-aminotetrazole, 5-amino-1-hydroxytetrazole, 1,5-pentamethylenetetrazole, 1-(2-dimethylaminoethyl)-5-mercaptotetrazole, 5-phenyltetrazole, and the like.

Examples of the indazole compound include 1H-indazole, 5-amino-1H-indazole, 5-nitro-1H-indazole, 5-hydroxy-1H-indazole, 6-amino-1H-indazole, 6-nitro-1H-indazole, 6-hydroxy-1H-indazole, 3-carboxy-5-methyl-1H-indazole, and the like.

Examples of the indole compound include 1H-indole, 1-methyl-1H-indole, 2-methyl-1H-indole, 3-methyl-1H-indole, 4-methyl-1H-indole, 5-methyl-1H-indole, 6-methyl-1H-indole, 7-methyl-1H-indole, 4-amino-1H-indole, 5-amino-1H-indole, 6-amino-1H-indole, 7-amino-1H-indole, 4-hydroxy-1H-indole, 5-hydroxy-1H-indole, 6-hydroxy-1H-indole, 7-hydroxy-1H-indole, 4-methoxy-1H-indole, 5-methoxy-1H-indole, 6-methoxy-1H-indole, 7-methoxy-1H-indole, 4-chloro-1H-indole, 5-chloro-1H-indole, 6-chloro-1H-indole, 7-chloro-1H-indole, 4-carboxy-1H-indole, 5-carboxy-1H-indole, 6-carboxy-1H-indole, 7-carboxy-1H-indole, 4-nitro-1H-indole, 5-nitro-1H-indole, 6-nitro-1H-indole, 7-nitro-1H-indole, 4-nitrile-1H-indole, 5-nitrile-1H-indole, 6-nitrile-1H-indole, 7-nitrile-1H-indole, 2,5-dimethyl-1H-indole, 1,2-dimethyl-1H-indole, 1,3-dimethyl-1H-indole, 2,3-dimethyl-1H-indole, 5-amino-2,3-dimethyl-1H-indole, 7-ethyl-1H-indole, 5-(aminomethyl)indole, 2-methyl-5-amino-1H-indole, 3-hydroxymethyl-1H-indole, 6-isopropyl-1H-indole, 5-chloro-2-methyl-1H-indole, and the like.

Examples of the thiazole compound include 2,4-dimethylthiazole and the like. Examples of the benzothiazole compound include 2-mercaptobenzothiazole and the like.

Examples thereof include the nonionic surfactants include higher alcohol derivatives where the lipophilic group (the group represented by R in the following examples) has 12 to 18 carbon atoms. Examples thereof include glycerin fatty acid esters (RCOOCH₂CH(OH)CH₂OH), sorbitan fatty acid esters, sucrose fatty acid esters, naturally occurring fatty acid esters, and the like. Also, examples thereof include fatty alcohol ethoxylates (RO(CH₂CH₂O)ₙH), polyoxyethylene alkylphenyl ethers (RC₆H₄O(CH₂CH₂O)ₙH), alkyl glycosides (RC₆H₁₁O₆), and the like.

The present polishing composition may contain one or two or more kinds of corrosion inhibitors. The content of the corrosion inhibitor in the present polishing composition is preferably 0.001 mass % or more and 5 mass % or less, more preferably 0.005 mass % or more and 1 mass % or less, and further preferably 0.01 mass % or more and 0.5 mass % or less, relative to the total mass of the polishing composition.

### <Dispersing Agent>

In the present polishing composition, in addition to the above components, a dispersing agent (or an aggregation inhibitor) may be contained as an optional component. The dispersing agent means one that is contained for stably dispersing abrasive grains in a dispersible medium such as pure water. As the dispersing agent, a common dispersing agent may be used. For example, examples thereof include anionic surfactants, cationic surfactants, amphoteric surfactants and anionic polymer compounds, cationic polymer compounds, and amphoteric polymer compounds, and one or two or more thereof may be contained.

The dispersing agent is preferably a polymer compound having a carboxy group, a sulfo group, a phosphonic acid group, a carboxylate group, a sulfonate group, or a phosphate group, and specific examples thereof include homopolymers of monomers having a carboxy group, a sulfo group, or a phosphoric acid group, such as acrylic acid, methacrylic acid, maleic acid, p-styrenesulfonic acid, or vinylphosphonic acid, and homopolymers in which the part of the carboxy group, sulfo group, or phosphonic acid group of the polymers forms a salt such as an ammonium salt. Moreover, preferable examples thereof include a copolymer of a monomer having a carboxy group, a sulfo group, or a phosphonic acid group with a monomer having a carboxylate group, a sulfonate group, or a phosphate group or a monomer having a carboxylate group, a sulfonate group, or a phosphate group, and a derivative thereof such as an alkyl ester with carboxylic acid. Furthermore, anionic surfactants such as polymer compounds such as polyvinyl alcohol, ammonium oleate, ammonium laurate, and triethanolamine lauryl sulfate.

Of these, as the dispersing agent, particularly, a polymer compound having a carboxy group or a salt thereof is preferred. Specific examples thereof include polyacrylic acid, polymers in which at least a part of the carboxy groups of polyacrylic acid is replaced with a carboxylic acid ammonium salt group (hereinafter referred to as ammonium polyacrylate), and the like. In the case of using a polymer compound such as ammonium polyacrylate, the weight-average molecular weight thereof is preferably 1,000 to 50,000, more preferably 2,000 to 30,000, and particularly preferably 3,000 to 25,000.

The content of the dispersing agent in the present polishing composition is, for the purpose of maintaining dispersion stability, preferably 0.001 mass % to 0.5 mass % and particularly preferably 0.001 mass % to 0.2 mass %, relative to the total mass of the polishing composition.

Moreover, the present polishing composition may appropriately contain a lubricant, a viscosity-imparting agent or viscosity control agent, an antiseptic agent, and the like, if necessary.

To the present polishing composition, an oxidizing agent may be added, but since the metal layer can be polished at a high removal rate without using any oxidizing agent, it is preferred that the composition substantially does not contain an oxidizing agent. Here, the term “substantially does not contain an oxidizing agent” means that any oxidizing agent is not actively included and the case where any oxidizing agent is unavoidably included is excluded. As the oxidizing agent which may be unavoidably included, examples thereof include an oxygen molecule in the air

As the oxidizing agent, typically, examples thereof include a peroxide having an oxygen-oxygen bond which forms radicals through dissociation of the oxygen-oxygen bond by the action of external energy such as heat or light. Examples of the peroxide-based oxidizing agent include hydrogen peroxide, persulfates, periodic acid, periodates such as potassium periodate, inorganic peroxides such as peroxocarbonates, peroxosulfates, and peroxophosphates, organic peroxides such as benzoyl peroxide, t-butyl hydroperoxide, cumene hydroperoxide, diisopropylbenzene hydroperoxide, performic acid, peracetic acid, and m-chloroperbenzoic acid. As the persulfic acid salts, examples thereof include ammonium persulfate, potassium persulfate, and the like. Moreover, examples of the oxidizing agent include iodates, bromates, persulfates, cerium nitrates, hypochloric acid, and ozone water.

In the common polishing composition for wiring formation, a high removal rate in the polishing of the metal layer is obtained by incorporating an oxidizing agent, while adverse effects such as corrosion of metal wiring and corrosion of a polishing apparatus are problems. When the present polishing composition does not contain an oxidizing agent, the metal layer can be polished at a high rate without causing the corrosion of metal wiring and corrosion of a polishing apparatus caused by such an oxidizing agent.

### <Preparation Method of Polishing Composition>

For preparing the present polishing composition, the compound (1) and cerium oxide particles that are essential components are added to a liquid medium containing water such as pure water or ion-exchange water and further, if necessary, a corrosion inhibitor and the like as an optional component are added, followed by mixing. At that time, preparation may be performed so that the pH of the obtained polishing composition falls within the above preferable range, by adding a pH adjusting agent, if necessary. In order to incorporate cerium oxide and the other abrasive grains to the present polishing composition, the following method is used: a method of adding the above individual components to a dispersion liquid in which the abrasive grains have been dispersed and mixing them. After mixing, by stirring for a predetermined time using a stirrer or the like, a homogeneous present polishing composition is obtained. Moreover, after mixing, a more satisfactory dispersion state can be also obtained using an ultrasonic dispersing machine.

The present polishing composition is not necessarily fed to the part to be polished as one where all the constituent components are mixed. At the time of feeding it to the part to be polished, the individual components may be mixed to afford the composition and pH of the polishing composition.

### <Polishing Method>

The present invention provides a polishing method of polishing a target surface of a semiconductor integrated circuit using the above polishing composition of the present invention. The polishing method of the present invention is a polishing method of feeding the present polishing composition to a polishing pad, bringing a target surface of a semiconductor integrated circuit device into contact with the polishing pad, and polishing the surface through relative motion between the target surface and the polishing pad, wherein the target surface includes a metal containing at least one selected from the group consisting of cobalt, ruthenium, and molybdenum, i.e., a metal M.

In the present invention, the “target surface” means a surface in an intermediate step, which appears the step of producing a semiconductor integrated circuit device. For example, in the polishing of the semiconductor integrated circuit device shown in FIG. 1 and FIG. 2, the metal layer, the polishing stopping layer, and the insulating layer may be polishing targets. In this case, the metal layer is present in the “target surface” and sometimes, the polishing stopping layer, and the insulating layer may be present in addition to the metal layer.

Moreover, the “metal layer” in the present invention means a layer composed of a planar metal layer but it refers to not only a layer spread over a surface as shown in FIG. 1 but also it include a layer as a collection of individual wirings as shown in FIG. 2. Moreover, the “metal layer” may be considered as including portions such as a via for electrically connecting the planar metal layer and the other portion.

In the polishing shown in FIG. 1 and FIG. 2, there are two stages of polishing steps of a first polishing step of polishing the metal layer 4 alone composed of the metal M and a second polishing step of polishing the metal layer 4, the polishing stopping layer 3, and the insulating layer 2. The polishing composition in the present invention may be used in any stages of the polishing steps. In the first polishing step using the present polishing composition, the metal layer 4 can be polished at a high rate. In the second polishing step using the present polishing composition, the metal layer 4, the polishing stopping layer 3, and the insulating layer 2 can be almost uniformly polished at a high removal rate and the planarization of the target surface is efficiently achieved.

As the insulating layer 2, a silicon oxide (SiO₂) film is common. As such a silicon oxide film, one obtained by depositing tetraethoxysilane (TEOS) by a CVD method is commonly used.

Recently, for the purpose of preventing wiring delay, the case where a low dielectric constant insulating layer is used instead of the SiO₂ film has been increased. As the material, examples thereof include a film composed of fluorine-added silicon oxide (SiOF), organic SOG (a film containing an organic component obtained by spin on glass) and a low dielectric constant material such as porous silica, and an SiOC film formed by a CVD method (chemical vapor deposition method).

As the organic silicon material of low dielectric constant material, examples thereof include trade name: Black Diamond (relative dielectric constant: 2.7, technology of Applied materials), trade name: Coral (relative dielectric constant: 2.7, technology of Novellus Systems), Aurora 2.7 (relative dielectric constant: 2.7, technology of Japan ASM), and the like, and particularly, compounds having an Si—CH₃ bond are preferably used. The present polishing composition can be suitably used in the case where these various insulating layers are employed.

Moreover, as the polishing stopping layer 3, an SiN layer, a TiN layer, and the like are common. The present polishing composition can be suitably used in the case where these various polishing stopping layers are employed. Since the present polishing composition does not contain any oxidizing agent, it is hardly found that SiN or the like denatures by oxidation to weaken the function as the polishing stopping layer and thus the control of polishing is made difficult, for example.

In the above polishing method, as the polishing apparatus, a common polishing apparatus may be used. FIG. 3 is a view of the polishing apparatus, as an example, which can be used for the polishing method of the present invention. The polishing apparatus 20 includes a polishing head 22 that holds a semiconductor integrated circuit device 21, a polishing platen 23, a polishing pad 24 attached to the surface of the polishing platen 23, and a feeding piping 26 that feeds a polishing composition 25 to the polishing pad 24. The apparatus is configured to perform polishing by bringing a target surface of the semiconductor integrated circuit device 21 held by the polishing head 22 into contact with the polishing pad 24 and subjecting the polishing head 22 and the polishing platen 23 to relative rotary motion while feeding the polishing composition 25 from the feeding piping 26. The polishing apparatus used in the embodiment of the present invention is not limited to one having such a structure.

The polishing head 22 may perform not only rotary motion but also linear motion. Moreover, the polishing platen 23 and the polishing pad 24 may have a size almost equal to or smaller than the size of the semiconductor integrated circuit device 21. In that case, it is preferable to relatively move the polishing head 22 and the polishing platen 23 such a manner that the whole surface of the target surface of the semiconductor integrated circuit device 21 can be polished. Furthermore, the polishing platen 23 and the polishing pad 24 may be those which do not perform rotary motion and, for example, they may be those that move to one direction by a belt-driven manner.

Polishing conditions for such a polishing apparatus 20 are not particularly limited, and polishing pressure can be increased to improve the removal rate by applying a load to the polishing head 22 to push it to the polishing pad 24. The polishing pressure is preferably about 0.5 kPa to 50 kPa and, from the viewpoints of uniformity of the removal rate within the target surface of the semiconductor integrated circuit device 21, planarity, and prevention of polishing defects such as scratch, the polishing pressure is more preferably about 3 kPa to 40 kPa. The number of rotations of each of the polishing platen 23 and the polishing head 22 is preferably about 50 rpm to 500 rpm, but is not limited thereto. Moreover, the feeding amount of the polishing composition 25 is appropriately adjusted and selected depending on the materials constituting the target surface and the composition of the polishing composition, the above polishing conditions or the like, and for example, in the case of polishing a wafer having a diameter of 200 mm, the feeding amount of approximately about 100 ml/min to 300 ml/min is preferred.

As the polishing pad 24, examples thereof include those composed of common nonwoven fabrics, foamed hard polyurethane, porous resins, non-porous resins, and the like. Moreover, in order to promote the feeding of the polishing composition 25 to the polishing pad 24 or accumulate a certain amount of the polishing composition 25 on the polishing pad 24, a groove having lattice shape, concentric shape, spiral shape, or the like may be formed on the surface of the polishing pad 24.

In addition, if necessary, polishing may be performed while bringing a pad conditioner into contact with the surface of the polishing pad 24 to perform conditioning of the surface of the polishing pad 24.

### Examples

The following specifically describes the present invention by Examples and Comparative Examples, but the present invention should not be construed as being limited to these Examples.

Cases 1 to 11 are Examples and Cases 12 and 13 are Comparative Examples. In the following cases, “%” means mass % unless otherwise stated. Moreover, characteristic values were measured and evaluated by the following methods.

[pH]

The pH was measured using a pH meter HM-30R manufactured by DKK-TOA Corporation.

### [Average Secondary Particle Diameter]

The average secondary particle diameter was measured using a laser dispersion/diffraction particle size distribution measuring apparatus (manufactured by Horiba Ltd., Apparatus name: LA-920).

### [Polishing Properties]

The polishing properties were evaluated by performing the following polishing using a full-automatic CMP polishing apparatus (manufactured by Applied Materials, Apparatus name: Mirra). For the polishing pad, a foamed hard polyurethane pad was used and, for conditioning of the polishing pad, a CVD diamond pad conditioner (manufactured by 3M Company, Trade name: Trizact B5) was used. As the polishing conditions, the polishing pressure was controlled to 13.8 kPa (2 psi), the number of rotations of the polishing platen was controlled to 80 rpm, and the number of rotations of the polishing head was controlled to 79 rpm. Moreover, the feeding rate of the abrasive grains was controlled to 200 mL/minute.

For measuring the removal rate [angstrom/min], as a polishing target (subject to be polished), the following (A) and (B) were prepared.

(A) A substrate with a silicon dioxide film, the silicon dioxide film having been formed on an 8-inch silicon wafer by plasma CVD using tetraethoxysilane as a raw material.

(B) A substrate with a ruthenium layer, the ruthenium layer having been present on an 8-inch silicon wafer.

For measuring the thickness of the silicon dioxide film formed on a substrate, a film thickness meter UV-1280SE of KLA-Tencor Company was used. Moreover, for measuring the thickness of the ruthenium layer, a resistivity measuring instrument VR300D manufactured by Kokusai Electric Semiconductor Service Inc.

### [Case 1]

Pure water, the compound (1Si-1).K⁺, polyacrylic acid, and a pH adjusting agent were mixed to manufacture a mixed liquid which was adjusted to obtain predetermined pH. The mixed liquid was further added to a cerium oxide dispersion liquid in which cerium oxide particles having an average primary particle diameter of 60 nm (average secondary particle diameter: 90 nm) were dispersed in pure water and mixed to obtain a polishing composition (1) having a pH of 9.0. The content of each component in the polishing composition (1) was as shown in Table 3.

### [Cases 2 to 4]

The polishing compositions (2) to (4) were obtained in the same manner as in Case 1 except that the content of the cerium oxide particles in Case 1 was changed. For the polishing compositions (1) to (4), the polishing properties were measured by the above methods. The results are shown in Table 3.

The compound (1Si-1).K⁺ is a compound where X⁺ is K⁺ in the compound (1Si-1). Hereinafter, as the compound (1Si-1).K⁺, the compound (1) is represented by the combination of abbreviation of each compound in Table 1 and a cation itself representing X⁺ or its abbreviation.

### [Cases 5 to 11]

The polishing compositions (5) to (11) in Cases 5 to 11 were prepared in the same manner as in Case 2 except that each compound (1) shown in Table 3 was used instead of the compound (1Si-1)K⁺ and the blending amount of cerium oxide and pH were adjusted to the numerical values shown in Table 3, and the polishing properties were measured by the above methods. The results are shown in Table 3.

### [Case 12]

The compound (1Si-1).K⁺ and water were mixed and further pH was adjusted to 10.0 with a pH adjusting agent to obtain a polishing composition (12). The content of each component in the polishing composition (12) are as shown in Table 3. For the polishing composition (12), the polishing properties were measured by the above methods. The results are shown in Table 3.

### [Case 13]

As Case 13, the polishing composition (13) was prepared in the same manner as in Case 3 except that the content of cerium oxide particles was adjusted to the numerical value shown in Table 3 and the compound (1) was not contained, and the polishing properties were measured by the above methods. The composition of the polishing composition (13) and evaluation results are shown in Table 3.

TABLE 3

| Case | | | 1 | 2 | 3 | 4 | 5 | 6 | 7 |
|---|---|---|---|---|---|---|---|---|---|
| Composition | Abrasive | Cerium oxide | 0.01 | 0.02 | 0.25 | 0.50 | 0.10 | 0.10 | 0.10 |
| [mass %] | grains | particles | | | | | | | |
| | Dispersing | Polyacrylic acid | 0.02 | 0.02 | 0.02 | 0.02 | 0.02 | 0.02 | 0.02 |
| | agent | | | | | | | | |
| | Compound | Compound | 0.100 | 0.100 | 0.100 | 0.100 | — | — | — |
| | (1) | (1Si-1)•K⁺ | | | | | | | |
| | | Compound | — | — | — | — | 0.045 | — | — |
| | | (1Si-21)•K⁺ | | | | | | | |
| | | Compound | — | — | — | — | — | 0.045 | — |
| | | (1Si-4)•NH₄⁺ | | | | | | | |
| | | Compound | — | — | — | — | — | — | 0.045 |
| | | (1Si-2)•(X-1) | | | | | | | |
| | | Compound | — | — | — | — | — | — | — |
| | | (1Si-5)•(X-3) | | | | | | | |
| | | Compound | — | — | — | — | — | — | — |
| | | (1Ni-3) | | | | | | | |
| | | Compound | — | — | — | — | — | — | — |
| | | (1Ni-4) | | | | | | | |

| pH | | 9.0 | 9.0 | 9.0 | 9.0 | 9.0 | 9.0 | 9.5 |
|---|---|---|---|---|---|---|---|---|
| Removal rate | Substrate (A): for polishing | 40 | 70 | 800 | 1300 | 660 | 490 | 670 |
| [Å/min] | evaluation of SiO₂ film | | | | | | | |
| | Substrate (B): for polishing | 90 | 90 | 70 | 70 | 60 | 40 | 50 |
| | evaluation of Ru layer | | | | | | | |

| Case | | | 8 | 9 | 10 | 11 | 12 | 13 |
|---|---|---|---|---|---|---|---|---|
| Composition | Abrasive | Cerium oxide | 0.10 | 0.25 | 0.25 | 0.25 | — | 0.25 |
| [mass %] | grains | particles | | | | | | |
| | Dispersing | Polyacrylic acid | 0.02 | 0.02 | 0.02 | 0.02 | — | 0.02 |
| | agent | | | | | | | |
| | Compound | Compound | — | — | — | — | 0.100 | — |
| | (1) | (1Si-1)•K⁺ | | | | | | |
| | | Compound | — | — | — | — | — | — |
| | | (1Si-21)•K⁺ | | | | | | |
| | | Compound | — | 0.045 | — | — | — | — |
| | | (1Si-4)•NH₄⁺ | | | | | | |
| | | Compound | — | — | — | — | — | — |
| | | (1Si-2)•(X-1) | | | | | | |
| | | Compound | 0.045 | — | — | — | — | — |
| | | (1Si-5)•(X-3) | | | | | | |
| | | Compound | — | — | 0.100 | — | — | — |
| | | (1Ni-3) | | | | | | |
| | | Compound | — | — | — | 0.100 | — | — |
| | | (1Ni-4) | | | | | | |

| pH | | 9.5 | 9.0 | 9.0 | 9.0 | 10.0 | 9.0 |
|---|---|---|---|---|---|---|---|
| Removal rate | Substrate (A): for polishing | 730 | 820 | 930 | 820 | 10 | 840 |
| [Å/min] | evaluation of SiO₂ film | | | | | | |
| | Substrate (B): for polishing | 50 | 70 | 50 | 140 | 30 | 0 |
| | evaluation of Ru layer | | | | | | |

From Table 3, it can be said that the polishing composition in Examples exhibits a high removal rate for the ruthenium layer. By changing the kind of the compound represented by the formula (1), it is possible to change the removal rate for the ruthenium layer. Moreover, by adjusting the concentration of cerium oxide abrasive grains, it is also possible to adjust arbitrarily the removal rate of the silicon dioxide film and the removal rate selectivity between the ruthenium layer and the silicon dioxide film.

This application is based on Japanese Patent Application No. 2019-027371 filed on Feb. 19, 2019 and Japanese Patent Application No. 2020-005516 filed on Jan. 16, 2020, the entire subject matters of which are incorporated herein by reference.

In the polishing composition and polishing method of the present invention, it is possible to polish a metal layer at a high removal rate without using an oxidizing agent in a composition used for CMP for the formation of wiring in a semiconductor integrated circuit device using a metal having low resistance and capable of being thinned, such as cobalt, ruthenium, or molybdenum, especially using the metal as an embedded wiring. Moreover, simultaneously, an insulating film such as a silicon dioxide film can be also polished at any removal rate. By the above, in the step of polishing the metal layer and the insulating layer, it becomes possible to polish the metal layer and the insulating layer evenly and it becomes possible to perform polishing that ensures the planarity of the target surface.
1: Semiconductor substrate
2: Insulating film
3: Polishing stopping layer
4: Metal layer
6: Embedded wiring
20: Polishing apparatus
21: Semiconductor integrated circuit device
22: Polishing head
23: Polishing platen
24: Polishing pad
25: Polishing composition
26: Feed piping

1. A polishing composition comprising a compound represented by the following formula (1), a cerium oxide particle, and water: 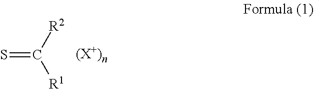
wherein R¹ is S⁻, SR¹¹ where R¹¹ is a hydrogen atom or a hydrocarbon group optionally containing a hetero atom, N⁻R¹² where R¹² is a hydrogen atom or a hydrocarbon group optionally containing a hetero atom, NR¹³R¹⁴ where R¹³ and R¹⁴ are each independently a hydrogen atom or a hydrocarbon group optionally containing a hetero atom, or R¹³ and R¹⁴ are combined with each other to form a heterocycle, or N=NR¹⁵ where R¹⁵ is a hydrocarbon group; R² is a hydrocarbon group optionally containing a hetero atom; X⁺ is a monovalent cation; n is 1 in the case where R¹ is S⁻ or N⁻R¹² and is 0 in the case where R¹ is other than S⁻ and N⁻R¹².

2. The polishing composition according to claim 1, wherein R¹ is S⁻ or SR¹¹, and R² is NR²³R²⁴ where R²³ and R²⁴ are each independently a hydrogen atom or a hydrocarbon group optionally containing a hetero atom, or R²³ and R²⁴ are combined with each other to form a heterocycle, provided that the case where R²³ and R²⁴ are a hydrogen atom is excluded, N=NR²⁵ where R²⁵ is a hydrocarbon group, or OR²⁶ where R²⁶ is a hydrocarbon group optionally containing a hetero atom.

3. The polishing composition according to claim 1, wherein R¹ is N⁻R¹², NR¹³R¹⁴, or N=NR¹⁵, and R² is NR⁴³R⁴⁴ where R⁴³ and R⁴⁴ are each independently a hydrogen atom or a hydrocarbon group optionally containing a hetero atom, or R⁴³ and R⁴⁴ are combined with each other to form a heterocycle, provided that the case where R⁴³ and R⁴⁴ are a hydrogen atom is excluded, or N=NR⁴⁵ where R⁴⁵ is a hydrocarbon group.

4. The polishing composition according to claim 1, which substantially does not contain an oxidizing agent.

5. The polishing composition according to claim 1, which further contains a dispersing agent.

6. The polishing composition according to claim 5, wherein the dispersing agent is a polymer compound having a carboxy group or a carboxylate group.

7. The polishing composition according to claim 1, having a pH of 2.0 or more and 11.0 or less.

8. The polishing composition according to claim 1, having a pH of 4.0 or more and 9.5 or less.

9. The polishing composition according to claim 1, wherein a content ratio of the compound is 0.0001 mass % or more and 10 mass % or less relative to a total mass of the polishing composition.

10. A polishing method, comprising:
feeding the polishing composition according to claim 1 to a polishing pad; and
bringing a target surface of a semiconductor integrated circuit device into contact with the polishing pad, and polishing the target surface through relative motion between the target surface and the polishing pad,
wherein the target surface includes a metal containing at least one selected from the group consisting of cobalt, ruthenium, and molybdenum.

11. The polishing method according to claim 10, that is for manufacturing a semiconductor integrated circuit device having a pattern where an embedded wiring of a metal containing at least one selected from the group consisting of cobalt, ruthenium, and molybdenum and an insulating layer are alternately arranged, wherein the insulating layer has a trench, and a metal layer composed of the metal, which is provided on the insulating layer so as to fill the trench, is polished using the polishing composition.
